(19) United States
(12) Patent Application Publication
(10) Pub. No.: US 2010/0301368 A1
(43) Pub. Date: Dec. 2, 2010

(54) ORGANIC LIGHT EMITTING DIODE

(75) Inventors: Choong-Youl Im, Yongin-City (KR); Kyung-Jin Yoo, Yongin-City (KR); Cheol-Ho Yu, Yongin-City (KR)

Correspondence Address: ROBERT E. BUSHNELL & LAW FIRM, 2029 K STREET NW, SUITE 600, WASHINGTON, DC, 20006-1004, US

(73) Assignee: SAMSUNG MOBILE DISPLAY CO., LTD., Yongin-City (KR)

(21) Appl. No.: 12/791,768

(22) Filed: Jun. 1, 2010

(30) Foreign Application Priority Data
Jun. 1, 2009 (KR) 10-2009-0048241

(51) Int. Cl. H01L 33/46; H01L 33/40

(52) U.S. Cl. 257/98; 257/E33.068; 257/E33.064

(57) ABSTRACT

Provided is an organic light emitting diode (OLED) including a substrate, a first electrode, a second electrode, and an organic layer disposed between the first and second electrodes. The first electrode includes an aluminum (Al)-based reflective film and a transparent conductive film that contacts the Al-based reflective film. The Al-based reflective film includes aluminum, a first element and nickel (Ni). In this structure, galvanic corrosion, which occurs due to a potential difference between electrodes, may not occur between the Al-based reflective film 5a and the transparent conductive film 5b. Accordingly, deterioration of the quality of OLED is prevented.

### CLAIM OF PRIORITY

This application makes reference to, incorporates the same herein, and claims all benefits accruing under 35 U.S.C. §119 from an application earlier filed in the Korean Intellectual Property Office on 1 Jun. 2009 and there duly assigned Serial No. 10-2009-0048241.

### BACKGROUND OF THE INVENTION

1. Field of the Invention

One or more embodiments of the present invention relate to an organic light emitting diode (OLED), and more particularly, to an OLED including a first electrode including an aluminum (Al)-based reflective film and a transparent conductive film. The OLED may have excellent thermal stability, light efficiency, and durability.

2. Description of the Related Art

Organic light emitting diodes (OLEDs), which are self-emitting type devices, have a wide viewing angle, excellent contrast, rapid response time, excellent brightness, excellent driving voltage, and high response speed, and may realize multicolored images.

A general OLED may have a structure in which an anode, a hole transfer layer (HTL), an emitting layer (EML), an electron transfer layer (ETL), and a cathode are sequentially formed on a substrate. The HTL, the EML, and the ETL are organic thin films formed of an organic compound.

An operating principle of the OLED having the structure described above is as follows. When a voltage is applied between the anode and the cathode, holes injected from the anode pass through the HTL and reach the EML and electrons injected from the cathode pass through the ETL and reach the EML. The holes and electrons are recombined with each other in the EML and excitons are generated. A state of the excitons is changed from an excited state to a ground state and thus light is emitted.

### SUMMARY OF THE INVENTION

One or more embodiments of the present invention include an organic light emitting diode (OLED) including an electrode including an aluminum (Al)-based reflective film and a transparent conductive film, wherein the OLED has excellent thermal stability, light efficiency, and durability.

Additional aspects will be set forth in part in the description which follows and, in part, will be apparent from the description, or may be learned by practice of the presented embodiments.

According to one or more embodiments of the present invention, an organic light emitting diode (OLED) includes a substrate; a first electrode formed on the substrate; a second electrode disposed on the first electrode; and an organic layer interposed between the first electrode and the second electrode, wherein the first electrode comprises an aluminum (Al)-based reflective film including a first element and nickel (Ni); and a transparent conductive film. The Al-based reflective film is disposed to be closer to the substrate than the transparent conductive film and the Al-based reflective film contacts the transparent conductive film. The first element includes one selected from the group consisting of lanthanum (La), cerium (Ce), praseodymium (Pr), promethium (Pm), samarium (Sm), europium (Eu), gadolinium (Gd), terbium (Tb), dysprosium (Dy), holmium (Ho), erbium (Er), thulium (Tm), lutetium (Lu), and combinations thereof.

The Al-based reflective film may include an phase, where x is in the range of about 2.5 to about 3.5. The phase may contact the transparent conductive film. ‘x’ may be 3.

The Al-based reflective film may include a Ni rich oxide layer on one surface thereof facing the transparent conductive film.

The amount of Ni in the Al-based reflective film may be in the range of about 0.6 weight % to about 5 weight %.

The first element may include lanthanum (La).

The amount of the first element may be about 0.1 weight % to about 3 weight %.

Thickness of the Al-based reflective film may be about 50 nm or greater.

The transparent conductive film may include indium tin oxide (ITO), indium zinc oxide (IZO), tin oxide (SnO₂), or zinc oxide (ZnO).

The thickness of the transparent conductive film may be about 5 nm to about 100 nm.

The first electrode may further include a metal layer. The metal layer may be formed between the Al-based reflective film and the substrate.

The metal layer may include one metal selected from the group consisting of molybdenum (Mo), tungsten (W), titanium (Ti), palladium (Pd), platinum (Pt), gold (Au), and combinations thereof.

The organic layer may include one selected from the group consisting of a hole injection layer (HIL), a hole transfer layer (HTL), an emitting layer (EML), a hole blocking layer (HBL), an electron transfer layer (ETL), an electron injection layer (EIL), and combinations thereof.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional diagram of an organic light emitting diode (OLED) according to an embodiment of the present invention;

FIG. 2A is a cross-sectional transmission electron microscope (TEM) image of an aluminum (Al)-based reflective film according to an embodiment of the present invention;

FIG. 2B shows a scanning transmission electron microscope (STEM)-high-angle annular dark-field (HAADF) image of the aluminum (Al)-based reflective film shown in FIG. 2A;

FIG. 2C shows graphs showing a result of analyzing components of abnormal grown grains of the aluminum (Al)-based reflective film of FIG. 2A; and

FIG. 3 is a photographic image of a cross-section of a first electrode according to another embodiment of the present invention;

FIG. 4A is a photographic image of an image of an OLED observed with the naked eye according to an embodiment of the present invention;

FIG. 4B is a microscopic image of a part of the image of FIG. 4A that is indicated by a dashed rectangle F; and

FIG. 5 is a cross-sectional diagram of an OLED according to another embodiment of the present invention.

### DETAILED DESCRIPTION OF THE INVENTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

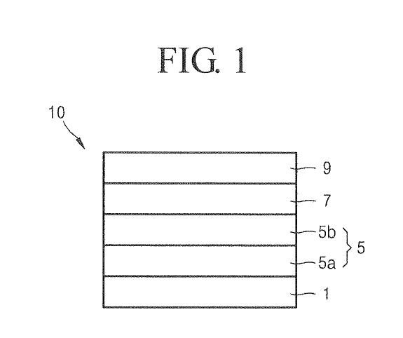

FIG. 1 is a cross-sectional diagram of an organic light emitting diode (OLED) 10 according to an embodiment of the present invention. Referring to FIG. 1, the OLED 10 according to the present embodiment has a structure in which a first electrode 5, an organic layer 7, and a second electrode 9 are sequentially formed in this order on a substrate 1. The first electrode 5 includes an aluminum (Al)-based reflective film 5a including a first element and nickel (Ni) and a transparent conductive film 5b. The Al-based reflective film 5a is disposed to be closer to the substrate 1 than the transparent conductive film 5b and contacts the transparent conductive film 5b.

The substrate 1 may be any substrate that is used in a general OLED and may be a glass substrate or a transparent plastic substrate having excellent mechanical strength, thermal stability, transparency, surface smoothness, tractability, and waterproofness.

The Al-based reflective film 5a includes aluminum (Al), a first element and nickel (Ni), and is formed on the substrate 1. The first element may further include lanthanum (La), cerium (Ce), praseodymium (Pr), promethium (Pm), samarium (Sm), europium (Eu), gadolinium (Gd), terbium (Tb), dysprosium (Dy), holmium (Ho), erbium (Er), thulium (Tm), lutetium (Lu), or combinations thereof.

The Al-based reflective film 5a has high reflectivity and thus the OLED 10 may have excellent light efficiency. Also, the Al-based reflective film 5a has high thermal stability based on the properties of Al so that durability thereof is excellent even if the Al-based reflective film 5a is exposed to a high-temperature manufacturing process. In addition, the Al-based reflective film 5a has excellent adhesive properties with an inorganic layer or an organic layer.

An Al-based reflective film including about 2 weight % of Ni and about 0.35 weight % of La is formed on a general thin film transistor (TFT) substrate and an indium-tin-oxide (ITO) transparent conductive film is formed on the Al-based reflective film. Then, the resultant is observed using a microscope. In a cathode connection portion, any removal or damage of the Al-based reflective film and the ITO transparent conductive film is not observed. Referring back to FIG. 1, the transparent conductive film 5h is disposed on the Al-based reflective film 5a and contacts the Al-based reflective film 5a. However, galvanic corrosion, which occurs due to a potential difference of electrodes, may not occur between the Al-based reflective film 5a and the transparent conductive film 5b.

Galvanic corrosion is an electrochemical process whereby a voltage is generated due to a potential difference between two different metals in electrical contact with each other, current flows, and electricity is generated. As such, the metal with greater activity (low potential) due to a difference in work function at the interface between the two metals acts as the anode and the metal with relatively low activity (high potential) acts as the cathode. When the two metals are exposed to a corrosive solution and corrosion is generated in the two metals due to the potential difference between the two metals, galvanic corrosion occurs. The anode, having greater activity, is quickly corroded and the cathode, having low activity, is slowly corroded. When the galvanic corrosion spreads along the interface between two electrode layers respectively formed of the different metals, contact resistance between the electrode layers is rapidly increased and unstable resistance dispersion may result. Accordingly, when an OLED having such electrode layers is driven, the colors of some pixel become more bright and the colors of other pixels become less bright, resulting in non-uniformity of brightness over the pixels. As a result, image quality may be poor. Thus, galvanic corrosion may be a factor that decreases the quality of OLEDs.

However, because the Al-based reflective film 5a includes the first element, which will be described later, galvanic corrosion may not be initiated between the Al-based reflective film 5a and the transparent conductive film 5b. Accordingly, the OLED according to the present embodiment may maintain high image quality over time.

An Al-based reflective film including about 2 weight % of Ni and about 0.35 weight % of La is formed on a general TFT substrate and an ITO transparent conductive film is formed on the Al-based reflective film. Then, the resultant is observed using a microscope. It is observed that galvanic corrosion does not occur between the Al-based reflective film and the ITO transparent conductive film.

The Al-based reflective film 5a includes Ni. As a result, the Al-based reflective film 5a may include an phase (here, x may be in the range of about 2.5 to about 3.5). ‘x’ may vary in the above range of about 2.5 to about 3.5.

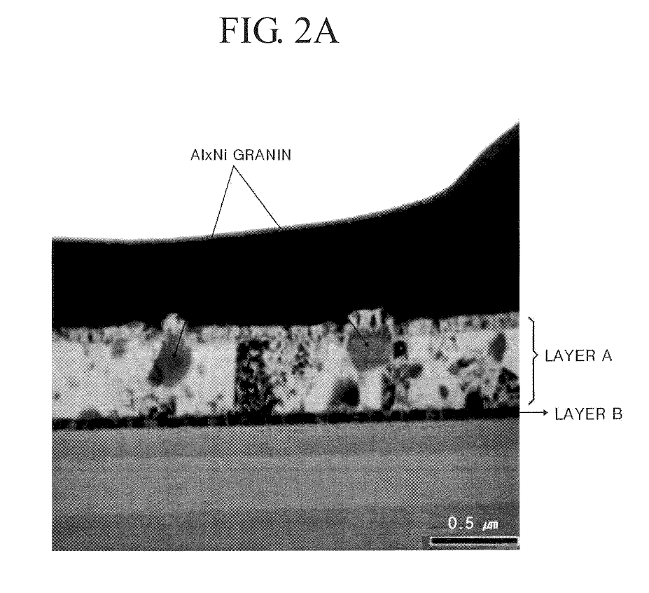

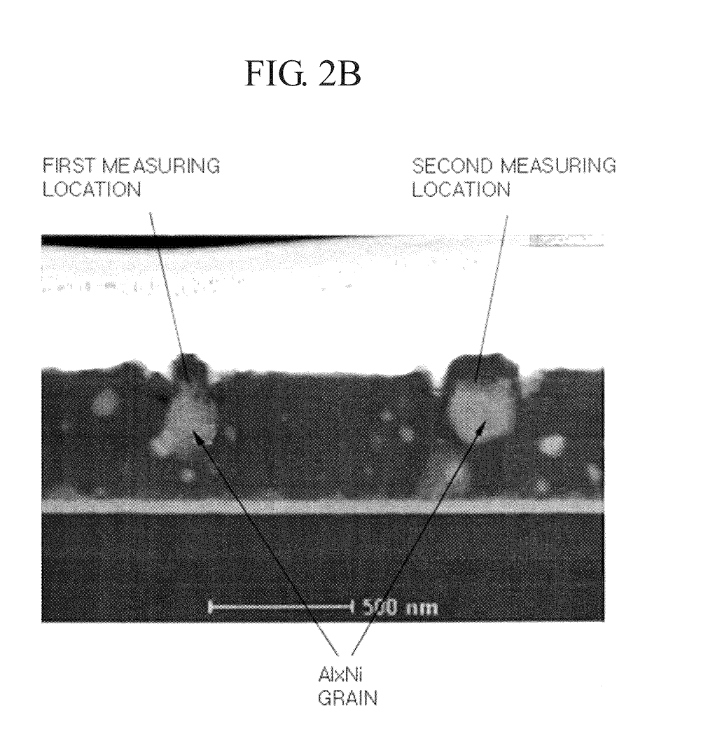

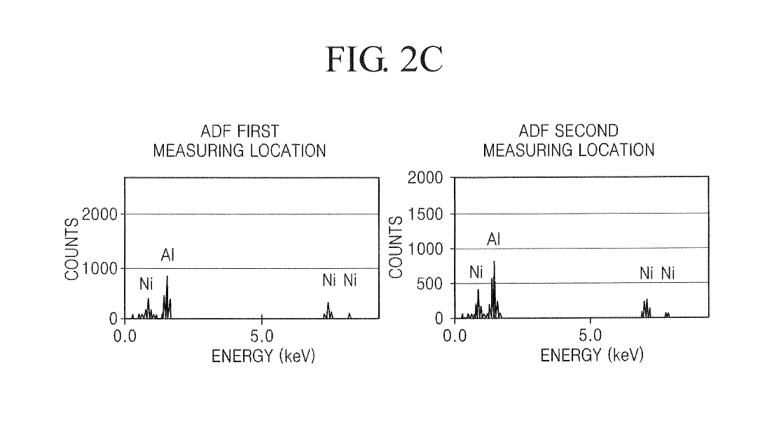

FIG. 2A is a cross-sectional transmission electron microscope (TEM) image of an Al-based reflective film (layer A) including about 2 weight % of Ni and about 0.35 weight % of La, formed on a Ti layer (layer B), FIG. 2B shows a scanning transmission electron microscope (STEM)-high-angle annular dark-field (HAADF) image of the aluminum (Al)-based reflective film shown in FIG. 2A, and FIG. 2C shows graphs showing a result of analyzing abnormal grown grains (a first measuring location and a second measuring location) observed as grey circular lumps using an energy dispersive spectrometer (EDS) semi-quantitative analysis. Accordingly, since Al and Ni exist in the abnormal grown grains of FIG. 2A with a ratio of about Al(K):Ni(K)=73:27 (based on atom %), the Al-based reflective film may include a material presumed to be AlₓNi (x is about 3).

The phase (here, x may be in the range of about 2.5 to about 3.5) may contact the transparent conductive film.

Also, a Ni rich oxide layer may exist on the surface of the Al-based reflective film 5a which faces the transparent conductive film 5b. For example, the Ni rich oxide layer may exist between the Al-based reflective film 5a and the transparent conductive film 5b in FIG. 1.

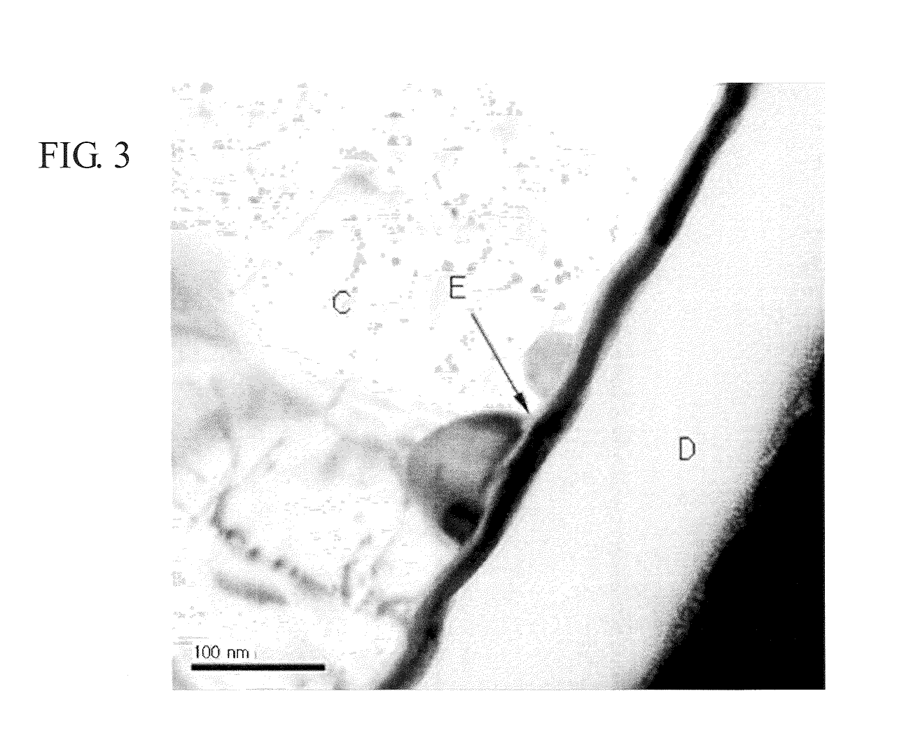

FIG. 3 is a photographic image of a cross-section of a first electrode according to another embodiment of the present invention. The Al-based reflective film C, includes about 2 weight % of Ni and about 0.35 weight % of La, and is formed on a general TFT substrate. The ITO transparent conductive film D is formed on the Al-based reflective film. In FIG. 3, a part of a white line (refer to a line represented by E), which is represented as an oblique line and formed between the Al-based reflective film and the ITO conductive film, is the Ni rich oxide layer. The thickness of the Ni rich oxide layer may be in the range of about 7 nm to about 8 nm.

An ohmic contact may be formed between the Al-based reflective film 5a and the transparent conductive film 5b due to the phase (here, x may be in the range of about 2.5 to about 3.5) and/or the Ni rich oxide layer described above.

The amount of Ni in the Al-based reflective film 5a may be in the range of about 0.6 weight % to about 5 weight %, for example, about 1 weight % to about 4 weight %. The amount of Ni in the OLED according to the present embodiment may be about 2 weight %. When the amount of Ni in the Al-based reflective film 5a is about 0.6 weight % or more, contact resistance stability between the Al-based reflective film 5a and the transparent conductive film 5b may be excellent. When the amount of Ni in the Al-based reflective film 5a is about 5 weight % or less, reflectivity and chemical resistance of the Al-based reflective film 5a may not be substantially decreased. The above amount of Ni is only an example and is not limited thereto.

The Al-based reflective film 5a further includes the first element, in addition to Ni. The first element may include La, Ce, Pr, Pm, Sm, Eu, Gd, Tb, Dy, Ho, Er, Tm, Lu, or combinations thereof.

As the Al-based reflective film 5a includes the first element described above, thermal stability may be improved and galvanic corrosion may be suppressed. For example, the first element may include La but is not limited thereto.

The amount of the first element may be in the range of about 0.1 to 3 weight %, for example, about 0.1 weight % to about 1 weight %. When the amount of the first element is about 0.1 weight % or more, thermal stability of Al in the Al-based reflective film 5a may not be substantially decreased. When the amount of the first element is about 3 weight % or less, decrease in reflectivity may be substantially prevented. The above amount of the first element is only an example and is not limited thereto.

The thickness of the Al-based reflective film 5a may be about 50 nm or above, for example, in the range of about 100 nm to about 500 nm. When the thickness of the Al-based reflective film 5a is about 50 nm or above, light generated from the organic layer 7 penetrates the Al-based reflective film 5A and thus decrease in light efficiency may be substantially prevented.

The transparent conductive film 5b may be a transparent and conductive metal oxide. Examples of the transparent conductive film 5B may include indium tin oxide (ITO), indium zinc oxide (IZO), tin oxide (SnO₂), or zinc oxide (ZnO). However, the transparent conductive film 5b is not limited thereto.

The thickness of the transparent conductive film 5b may be in the range of about 5 nm to about 100 nm, for example, about 7 nm to about 80 nm. When the thickness of the transparent conductive film 5B is in the above range, decrease in reflectivity of the Al-based reflective film 5a may be minimized and the first electrode having a high efficiency may be realized.

The organic layer 7 is formed on the transparent conductive film 5b. In this specification, the “organic layer” denotes all layers interposed between a first electrode and a second electrode and may include a metal complex. Thus, the organic layer is not always formed of an organic material.

The organic layer 7 may include a hole injection layer (HIL), a hole transfer layer (HTL), an emitting layer (EML), a hole blocking layer (HBL), an electron transfer layer (ETL), an electron injection layer (EIL), or combinations thereof.

The HIL may be formed on the first electrode 5 by using a method such as vacuum deposition, spin coating, casting, or Langmuir-Blodgett (LB) deposition.

If the HIL is formed using vacuum deposition, the deposition conditions may vary according to a compound used as a material for forming the HIL, and a structure and thermal characteristics of the HIL. For example, the deposition temperature may be in the range of about 100 to about 500° C., the degree of vacuum may be in the range of about 10⁻⁸ to about 10⁻³ torr, and deposition speed may be in the range of about 0.01 to about 100 Å/sec.

If the HIL is formed using spin coating, the coating conditions may vary according to a compound used as a material for forming the HIL, and a structure and thermal characteristics of the HIL. Coating speed may be in the range of about 2000 rpm to about 5000 rpm and a heat-treatment temperature for removing a solvent after coating may be in the range of about 80° C. to about 200° C.

The material for forming the HIL may be a well-known hole injection material. Examples of the material may include a phthalocyanine compound such as copper phthalocyanines, m-MTDATA [4,4′,4″-tris(3-methylphenylphenylamino)triphenylamine], NPB(N,N′-di(1-naphthyl)-N,N′-diphenyl benzidine(N,N′-di(1-naphthyl)-N,N′-diphenylbenzidine)), TDATA, 2T-NATA, Pani/DBSA (Polyaniline/Dodecylbenzenesulfonic acid), PEDOT/PSS(Poly(3,4-ethylenedioxythiophene)/Poly(4-styrenesulfonate), Pani/CSA (Polyaniline/Camphor sulfonicacid), or PANT/PSS (Polyaniline)/Poly(4-styrenesulfonate). However, the material for forming the HIL is not limited thereto.

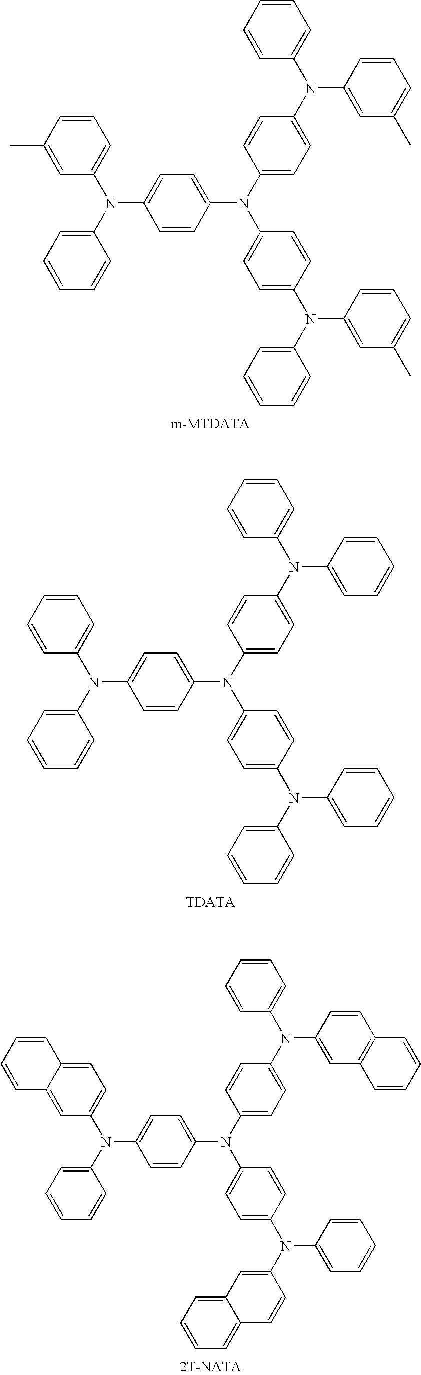

The thickness of the HIL may be in the range of about 100 Å to about 10000 Å, for example, about 100 Å to about 1000 Å. When the thickness of the HIL is in the above range, satisfactory hole injecting characteristics may be obtained without an increase in a driving voltage of the OLED.

Then, the hole transfer layer (HTL) may be formed on the hole injection layer (HIL) by using a method such as vacuum deposition, spin coating, casting, or LB deposition. If the HTL is formed using vacuum deposition or spin coating, deposition or coating conditions may vary according to compounds used. However, in general, the conditions may be similar to those used to form the HIL.

The material for forming the HTL may be a well-known hole transfer material. Examples of the material may include a carbazol derivative such as N-phenylcarbazol, polyvinyl carbazole, an amine derivative having an aromatic fused ring such as N,N′-bis(3-methylphenyl)-N,N′-diphenyl-[1,1-biphenyl]-4,4′-diamine (TPD) and N,N′-di(naphthalen-1-yl)-N,N′-diphenyl benzidine (α-NPD), and a triphenylamine-based material such as 4,4′,4″-tris(N-carbazolyl)triphenylamine) (TCTA). Here, TCTA may prevent dispersion of the excitons from the EML, in addition to the function of transferring holes.

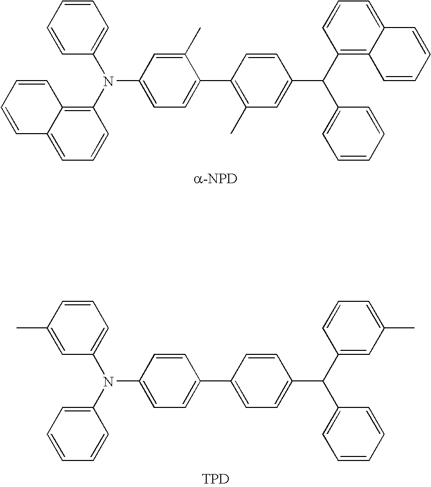

The thickness of the HTL may be in the range of about 50 Å to about 1000 Å, for example, about 100 Å to about 800 Å. When the thickness of the HTL is in the above range, satisfactory hole transferring characteristics may be obtained without an increase in the driving voltage of the OLED.

The emitting layer (EML) may be formed on the hole transfer layer (HTL) by using a method such as vacuum deposition, spin coating, casting, or LB deposition. When the EMI, is formed using vacuum deposition or spin coating, the deposition or coating conditions may vary according to compounds used. However, in general, the conditions may be similar to those used to form the hole injection layer (HIL).

The EML may include one compound or a combination of a host and a dopant. Examples of the host may include Alq₃, 4,4′-N,N′-dicabazole-biphenyl (CBP), poly(n-vinylcarbazole (PVK), 9,10-di(naphthalen-2-yl)anthracene (ADN), TCTA, 1,3,5-tris(N-phenylbenzimidazole-2-yl)benzene (TPBI), 3-tert-butyl-9,10-di(napth-2-yl)anthracene (TBADN), E3, distyrylarylene (DSA). However, the host is not limited thereto.

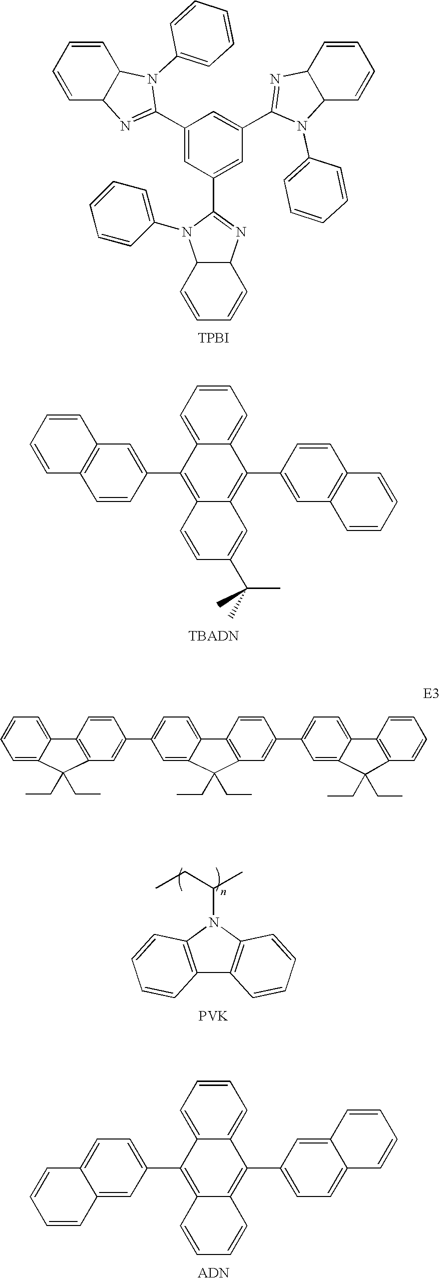

A red dopant may be a well-known red dopant such as PtOEP, Ir(piq)₃, Btp₂Ir(acac), or DCJTB. However, the red dopant is not limited thereto.

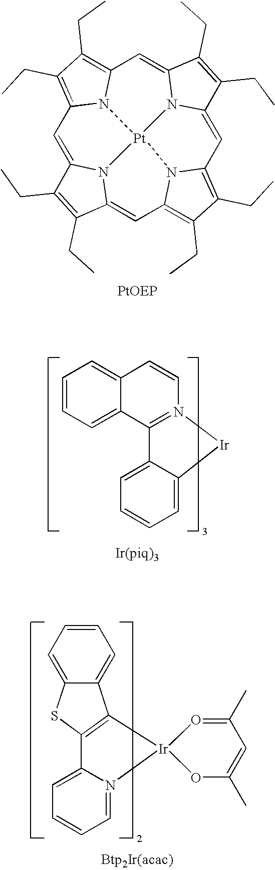

A green dopant may be a well-known green dopant such as Ir(ppy)₃ (ppy is phenyl pyridine), Ir(ppy)₂(acac), Ir(mpyp)₃, or C545T. However, the green dopant is not limited thereto.

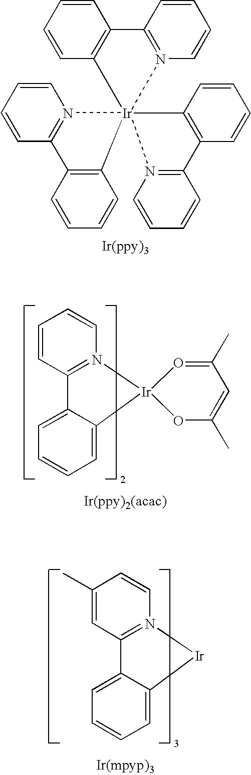

A blue dopant may be a well-known blue dopant such as F₂Irpic, (F₂ ppy)₂Ir(tmd), Ir(dfppz)₃, ter-fluorene, 4,4′-bis(4-diphenylaminostyryl)biphenyl (DPAVBi), or 2,5,8,11-tetra-t-butylperylene (TBPe). However, the blue dopant is not limited thereto.

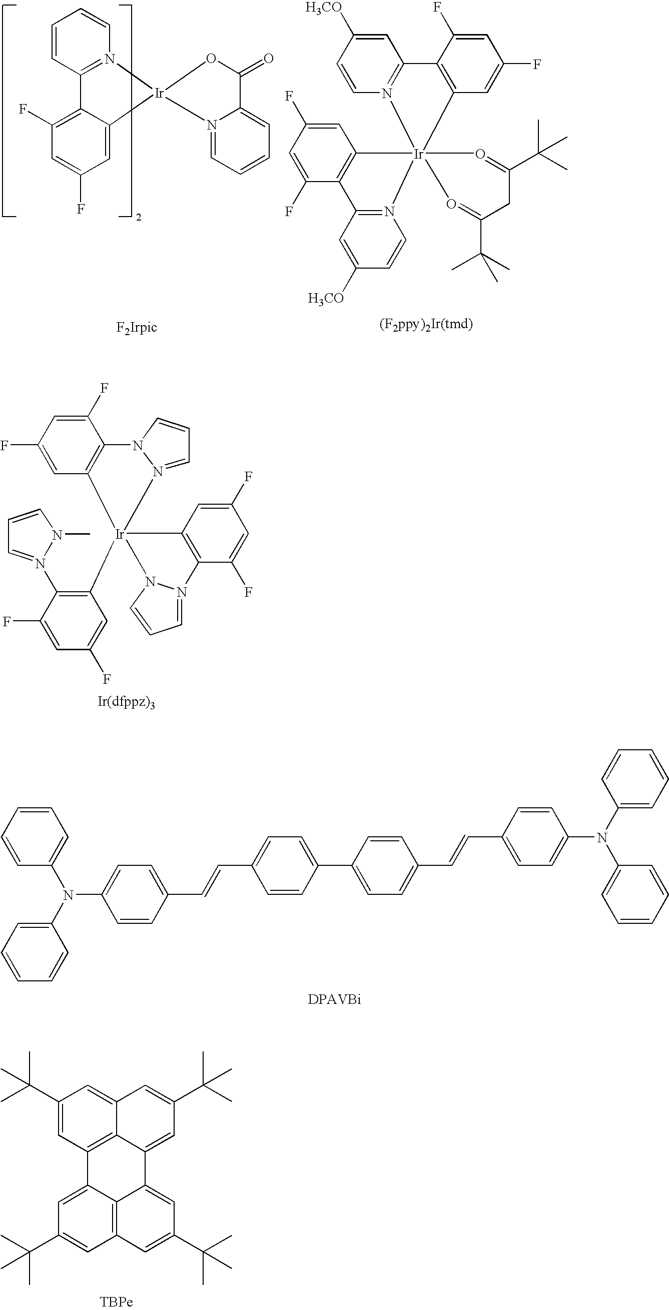

When the dopant and the host are used together, the doping concentration of the dopant is not limited. However, in general, the amount of dopant may be in the range of about 0.01 parts by weight to about 15 parts by weight based on 100 parts by weight of the host.

The thickness of the emitting layer (EML) may be in the range of about 100 Å to about 1000 Å, for example, about 200 Å to about 600 Å. When the thickness of the EML is in the above range, excellent emitting characteristics may be obtained without an increase in the driving voltage of the OLED.

When a phosphorescent dopant is used in the EML, the hole blocking layer (HBL) may be formed between the hole transfer layer (HTL) and the EML by using a method such as vacuum deposition, spin coating, casting, or LB deposition in order to prevent dispersion of triplet excitons or holes to the HTL. When the HBL is formed using vacuum deposition or spin coating, the deposition or coating conditions thereof may vary according to compounds used. However, in general, the conditions may be similar to those used to form the hole injection layer (HIL). A material for forming the HBL may be a well-known hole blocking material. Examples of the material may include an oxadiazole derivative, a triazole derivative, and a phenanthroline derivative.

The thickness of the HBL may be in the range of about 500 Å to about 1000 Å, for example, about 100 Å to about 300 Å. When the thickness of the HBL is in the above range, excellent hole blocking characteristics may be obtained without an increase in the driving voltage of the OLED.

Then, the electron transfer layer (ETL) may be formed on the EML or the HBL using a method such as vacuum deposition, spin coating, or casting. When the ETL is formed using vacuum deposition or spin coating, the deposition or coating conditions thereof may vary according to compounds used. However, in general, the conditions may be similar to those used to form the HIL. A material for forming the ETL may stably transfer electrons injected from an electron injection electrode (cathode) and may include an electron transfer material. Examples of the material may include a quinoline derivative, for example, tris(8-quinolinolate)aluminum (Alq3), TAZ, and Balq. However, the material for forming the ETL is not limited thereto.

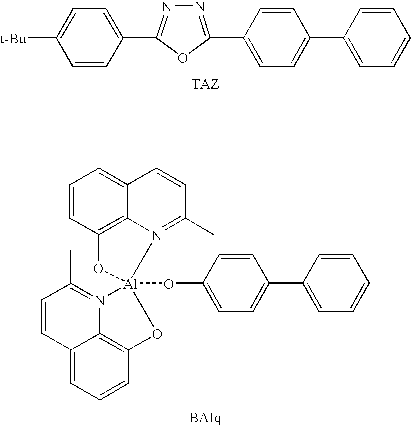

The thickness of the ETL may be in the range of about 100 Å to about 1000 Å, for example, about 150 Å to about 500 Å. When the thickness of the ETL is in the above range, satisfactory electron transfer characteristics may be obtained without a decrease in the driving voltage of the OLED.

In addition, the electron injection layer (EIL) for facilitating injection of electrons from the cathode may be formed on the ETL and a material for forming the EIL is not limited.

The material for forming the EIL may be any material used as an electron injection material such as LiF, NaCl, CsF, Li2O, or BaO. The EIL may be formed using a method such as vacuum deposition, spin coating, casting, or Langmuir-Blodgett (LB) deposition. The deposition or coating conditions may vary according to a compound used. However, in general, the conditions may be similar to those used to form the HIL.

The thickness of the EIL may be in the range of about 1 Å to about 100 Å, for example, about 5 Å to about 90 Å. When the thickness of the EIL is in the above range, excellent electron injection characteristics may be obtained without an increase in the driving voltage of the OLED.

The second electrode 9, which is a transmissive electrode, is formed on the organic layer 7. The second electrode 9 may be the electron injection electrode, that is, the cathode. A material for forming the second electrode 9 may include a metal having a low work function, an alloy, an electrically conductive compound, or a mixture thereof. Examples of the material for forming the second electrode 9 may include a thin film formed of lithium (Li), magnesium (Mg), aluminum (Al), aluminum-lithium (Al—Li), calcium (Ca), magnesium-indium (Mg—In), or magnesium-silver (Mg—Ag). In addition, in order to obtain a top emission device, the transparent electrode or semi-transparent electrode may be formed using ITO or IZO.

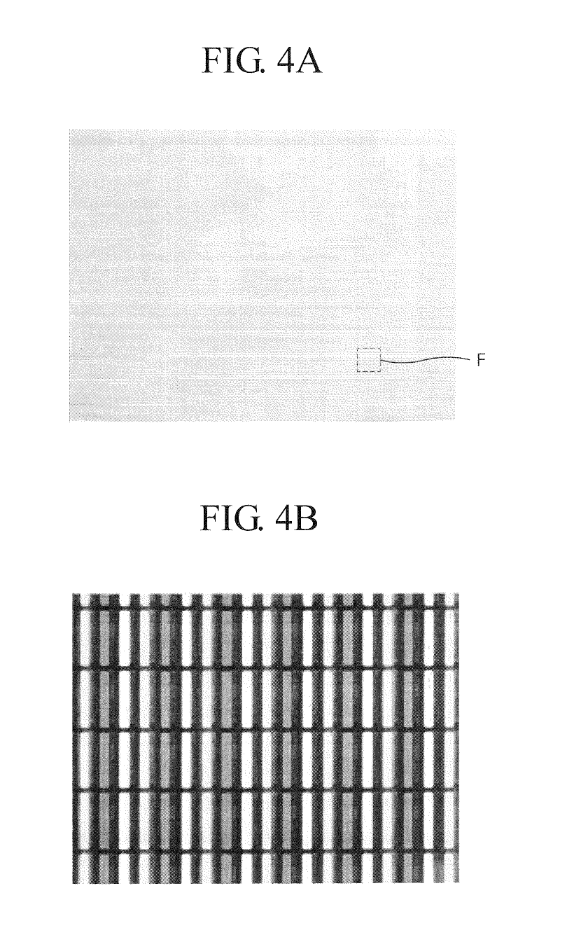

FIG. 4A is a photographic image of an OLED observed with the naked eye and FIG. 4B is a microscopic image of a part of the image of FIG. 4A. Referring to FIG. 4A, an Al-based reflective film having a thickness of about 125 nm and including Ni and La (the amount of Ni is about 2 weight % and the amount of La is about 0.35 weight %), and an ITO transparent conductive film having a thickness of about 70 nm are sequentially formed on a TFT substrate. The Al-based reflective film and the ITO transparent conductive film together constitute a first electrode. Then, a general organic layer and a transparent cathode are sequentially formed on the ITO transparent conductive film so as to form an OLED and the OLED is driven and observed with the naked eye. In FIG. 4B, a part marked by a dashed rectangle F in the image of FIG. 4A is observed using a microscope.

FIGS. 3A and 3B show that the OLED including the first electrode constituted as described above may provide uniform brightness and clear images.

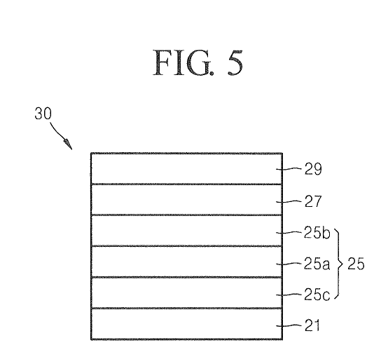

FIG. 5 is a cross-sectional diagram of an OLED 20 according to another embodiment of the present invention. Referring to FIG. 5, the OLED 20 according to the present embodiment includes a substrate 21, a first electrode 25, an organic layer 27, and a second electrode 29. The first electrode 25 includes a metal layer 25c, an Al-based reflective film 25a including Ni and a first element, and a transparent conductive film 25b sequentially formed on the substrate 21 in this order. Here, the substrate 21, the organic layer 27, the second electrode 29, the Al-based reflective film 25a including Ni and a first element, and the transparent conductive film 25b are similar to those of the embodiment described referring to FIG. 1.

Referring to FIG. 5, the first electrode 25 in the OLED 20 further includes the metal layer 25c. The metal layer 25c may be interposed between the Al-based reflective film 25a, including Ni and a first element, and the substrate 21. For example, the metal layer 25c may be formed on a surface of the Al-based reflective film 25a which does not contact the transparent conductive film 25b.

The metal layer 25c may be a barrier layer for dispersion of Al components in the Al-based reflective film 25a included in the first electrode 25.

The metal layer 25c may include a metal such as molybdenum (Mo), tungsten (W), titanium (Ti), palladium (Pd), platinum (Pt), gold (Au), or combination thereof. However, the metal layer 25c is not limited thereto. For example, the Al-based reflective film in FIG. 2A may be formed on a Ti layer.

The thickness of the metal layer 25c may be in the range of about 20 nm to about 200 nm, for example, about 50 nm to about 100 nm. When the thickness of the metal layer 25c is in the above range, dispersion of the Al components may be prevented. However, the thickness of the metal layer 25c is not limited thereto.

As described above, according to the one or more of the above embodiments of the present invention, an OLED including a first electrode as described above may have excellent thermal stability, light efficiency, and durability.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. An organic light emitting diode (OLED) comprising:
a substrate;
a first electrode formed on the substrate;
a second electrode disposed on the first electrode; and
an organic layer interposed between the first electrode and the second electrode, the first electrode comprising:
an aluminum (Al)-based reflective film comprising a first element and nickel (Ni); and
a transparent conductive film, the Al-based reflective film being disposed to be closer to the substrate than the transparent conductive film, the Al-based reflective film contacting the transparent conductive film, the first element comprising one selected from the group consisting of lanthanum (La), cerium (Ce), praseodymium (Pr), promethium (Pm), samarium (Sm), europium (Eu), gadolinium (Gd), terbium (Tb), dysprosium (Dy), holmium (Ho), erbium (Er), thulium (Tm), lutetium (Lu), and combinations thereof.

2. The OLED of claim 1, wherein the Al-based reflective film comprises an phase, where x is in the range of about 2.5 to about 3.5.

3. The OLED of claim 2, wherein the phase contacts the transparent conductive film.

4. The OLED of claim 2, wherein x is 3.

5. The OLED of claim 1, wherein the Al-based reflective film comprises a Ni rich oxide layer on a surface thereof facing the transparent conductive film.

6. The OLED of claim 1, wherein the amount of Ni in the Al-based reflective film is in a range of about 0.6 weight % to about 5 weight %.

7. The OLED of claim 1, wherein the first element comprises lanthanum (La).

8. The OLED of claim 1, wherein the amount of the first element is about 0.1 weight % to about 3 weight %.

9. The OLED of claim 1, wherein the thickness of the Al-based reflective film is about 50 nm or greater.

10. The OLED of claim 1, wherein the transparent conductive film comprises indium tin oxide (ITO), indium zinc oxide (IZO), tin oxide (SnO₂), or zinc oxide (ZnO).

11. The OLED of claim 1, wherein the thickness of the transparent conductive film is about 5 nm to about 100 nm.

12. The OLED of claim 1, wherein the first electrode further comprises a metal layer, the metal layer being formed between the Al-based reflective film and the substrate.

13. The OLED of claim 12, wherein the metal layer comprises one metal selected from the group consisting of molybdenum (Mo), tungsten (W), titanium (Ti), palladium (Pd), platinum (Pt), gold (Au), and combinations thereof.

14. The OLED of claim 1, wherein the organic layer comprises one selected from the group consisting of a hole injection layer (HIL), a hole transfer layer (HTL), an emitting layer (EML), a hole blocking layer (HBL), an electron transfer layer (ETL), an electron injection layer (EIL), and combinations thereof.
